(19) United States
(12) Patent Application Publication
(10) Pub. No.: US 2026/0319029 A1
(43) Pub. Date: Oct. 15, 2026

(54) NANOMAGNETIC PARTICLE SECURITY SYSTEM

(71) Applicant: Microchip Technology Inc., Chandler, AZ (US)

(72) Inventors: Steve Nagel, Chandler, AZ (US); Bomy Chen, Newark, CA (US)

(73) Assignee: Microchip Technology Inc., Chandler, AZ (US)

(21) Appl. No.: 19/239,668

(22) Filed: Jun. 16, 2025

Related U.S. Application Data
(60) Provisional application No. 63/785,669, filed on Apr. 9, 2025.

(51) Int. Cl. G01R 33/09; B82Y 15/00; B82Y 25/00; B82Y 40/00

(52) U.S. Cl. CPC G01R 33/091; B82Y 15/00; B82Y 25/00; B82Y 40/00

(57) ABSTRACT

A nanomagnetic sticker is disclosed. The nanomagnetic sticker includes a base layer and an adhesive layer located on a first side of the base layer. The nanomagnetic sticker also includes a print layer located on a second side of the base layer, the print layer comprising patterned ink. The nanomagnetic sticker further includes a plurality of nanomagnetic particles embedded in at least one of the adhesive layer and the patterned ink.

### PRIORITY

This application claims priority to commonly owned United States Provisional Patent Application No. 63/785,669 filed Apr. 9, 2025, the entire contents of which are hereby incorporated by reference for all purposes.

### TECHNICAL FIELD

The present disclosure relates to security systems and methods. Various examples of the teachings herein include security systems and methods utilizing nanomagnetic particles to detect and prevent theft.

### BACKGROUND

Retail stores suffer estimated losses of $13 billion per year in the United States due to theft. Worldwide, retail stores suffer estimated losses of almost $150 billion per year due to theft. The inventors of various examples in the present disclosure have recognized that the cost of anti-theft deterrents, and the ability to apply anti-theft deterrents to retail products, presents a hurdle for retailers to effectively implement theft deterrent systems. Some currently available theft deterrent systems utilize radio-frequency identification (RFID) tags applied to retail products to identify and prevent theft. The use of RFID tags adds cost to every product to which an RFID tag is applied. Thus, it may not be practical to apply RFID tags to products that are inexpensive or are sold with low margins. Further, many smaller or oddly-shaped products may not have a suitable size or surface on which an RFID tag may be applied. An alternative theft deterrent system includes the use of an anti-theft barcode sticker with an integrated magnetic strip. Currently available anti-theft barcode stickers include a barcode printed in ink on a thick plastic case with an elongated magnetic strip implanted in the plastic case. Much like RFID tag systems, the use of anti-theft barcode stickers add significant costs to products to which they are attached. Thus, it may not be practical to apply anti-theft barcode stickers to products that are inexpensive or are sold with low margins. Further, the thick plastic case of an anti-theft barcode sticker, and the elongated magnetic strip implanted therein, may prevent such anti-theft barcode stickers from being applied to small or oddly-shaped products. The various examples described in the present disclosure may address one or more of these challenges.

### SUMMARY

The examples herein describe systems and methods for deterring theft of retail products in a cost-efficient manner by utilizing nanomagnetic stickers or nanomagnetic barcodes applied to commercial products that may be detected by panel including a two-dimensional array of magnetic sensor cells.

According to one example, a nanomagnetic sticker is provided that includes a base layer; an adhesive layer located on a first side of the base layer; a print layer located on a second side of the base layer, the print layer comprising patterned ink; and a plurality of nanomagnetic particles embedded in at least one of the adhesive layer and the patterned ink. In an example, the plurality of nanomagnetic particles are embedded in the adhesive layer. In the same or different examples, the plurality of nanomagnetic particles are embedded in the patterned ink. In the same or different examples, the plurality of nanomagnetic particles are embedded in the adhesive layer and in the patterned ink. In the same or different examples, the patterned ink forms a bar code. In the same or different examples, the base layer comprises paper. In the same or different examples, the base layer comprises plastic. In the same or different examples, the nanomagnetic sticker is wrapped in a roll disposed around a magnetic core. In the same or different examples, the magnetic core comprises neodymium-iron-boron (NdFeB).

According to one example, a magnetic detection system is provided that includes a plurality of sensor cells arranged in a two-dimensional array, wherein each of the plurality of sensor cells includes a tunnel magnetoresistance (TMR) sensor and a transistor coupled to enable the TMR sensor; and a control circuit configured to periodically scan each of the plurality of sensor cells. In an example, the transistor is a thin-film transistor. In the same or different examples, the control circuit is configured to detect a location of a nanomagnetic sticker or a nanomagnetic barcode based on a plurality of sense signals from the plurality of sensor cells located across the two-dimensional array. In the same or different examples, the nanomagnetic barcode includes a plurality of nanomagnetic particles embedded in patterned ink forming a barcode. In the same or different examples, the nanomagnetic sticker comprises a base layer; an adhesive layer located on a first side of the base layer; a print layer located on a second side of the base layer, the print layer comprising patterned ink; and a plurality of nanomagnetic particles embedded in at least one of the adhesive layer and the patterned ink. In the same or different examples, the plurality of nanomagnetic particles are embedded in the adhesive layer. In the same or different examples, the plurality of nanomagnetic particles are embedded in the patterned ink. In the same or different examples, the plurality of nanomagnetic particles are embedded in the adhesive layer and in the patterned ink.

Another example provides a method for fabricating, or for fabricating and detecting, a nanomagnetic sticker. The method may include forming a sticker having a base layer and an adhesive layer located on a first side of the adhesive layer, forming a print layer on a second side of the base layer including patterned ink, embedding a plurality of nanomagnetic particles in at least one of the patterned ink and the adhesive layer, and magnetizing the plurality of nanomagnetic particles. In an example, magnetizing the plurality of nanomagnetic particles includes placing the sticker in a roll around a magnetic core. In the same or different examples, the magnetic core comprises neodymium-iron-boron (NdFeB). In the same or different examples, the plurality of nanomagnetic particles are embedded in the adhesive layer. In the same or different examples, the plurality of nanomagnetic particles are embedded in the patterned ink. In the same or different examples, the plurality of nanomagnetic particles are embedded in the patterned ink and the adhesive layer. In the same or different examples, the method further includes detecting a location of the sticker with a magnetic detection system including a plurality of sensor cells arranged in a two-dimensional array.

### BRIEF DESCRIPTION OF THE DRAWINGS

A more complete understanding may be acquired by referring to the following description taken in conjunction with the accompanying drawings, in which like reference numbers indicate like features.

FIG. 1 illustrates a side cross-section view of nanomagnetic sticker in accordance with various examples described in the present disclosure.

FIG. 2 illustrates a side cross-section view of nanomagnetic sticker in accordance with various examples described in the present disclosure.

FIG. 3 illustrates a side cross-section view of nanomagnetic sticker in accordance with various examples described in the present disclosure.

FIG. 4 illustrates a perspective view of a retail product with a nanomagnetic barcode in accordance with various examples described in the present disclosure.

FIG. 5 illustrates a perspective view of a roll of nanomagnetic stickers in accordance with various examples described in the present disclosure.

FIG. 6A illustrates a schematic diagram of a magnetic detection system in accordance with various examples described in the present disclosure.

FIG. 6B illustrates a magnetic detection system in accordance with various examples described in the present disclosure.

FIG. 7 illustrates a security system in accordance with various examples described in the present disclosure.

FIG. 8 illustrates a flow chart of an example method for fabricating a nanomagnetic sticker in accordance with various examples described in the present disclosure.

FIG. 9 illustrates a flow chart of an example method for detecting a nanomagnetic sticker in accordance with various examples described in the present disclosure.

### DETAILED DESCRIPTION

The following description sets forth example aspects of the present disclosure. Such description is not intended as a limitation on the scope of the present disclosure. Rather, the description also encompasses combinations and modifications to those example aspects described herein.

The inventors of various examples described in the present disclosure have recognized the benefit of theft deterrent systems that can be utilized in a cost effective manner for a large range of products, including products that are sold at a low price or with low profit margins. This disclosure presents a detection system that may utilize nanomagnetic barcodes or nanomagnetic stickers. The nanomagnetic barcodes or nanomagnetic stickers may have nanomagnetic particles embedded therein. The nanomagnetic particles may be embedded, for example, in an adhesive layer, in patterned ink forming a barcode, or in both the adhesive layer and the patterned ink forming the barcode. The nanomagnetic particles may be magnetized to allow detection thereof. The detection system may also include a two-dimensional array of magnetic sensors formed together in a panel. As described in further detail below, the array of magnetic sensors may be formed in a panel that may be utilized to detect the presence and specific location of a retail product with a nanomagnetic barcode or nanomagnetic barcode sticker applied.

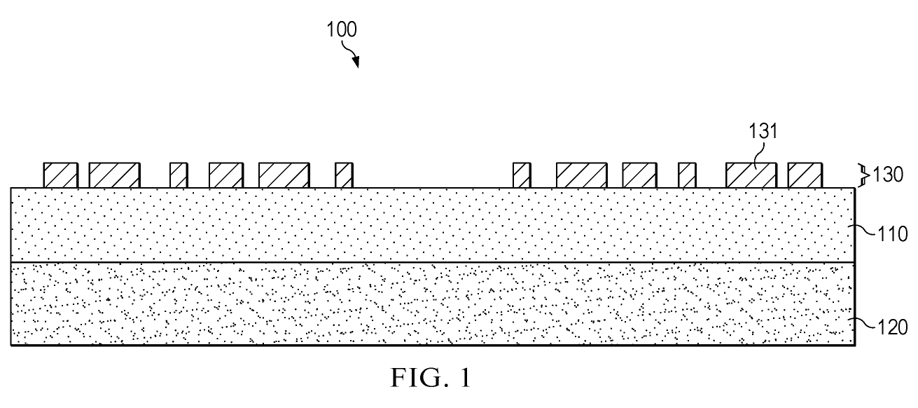

FIG. 1 illustrates a side cross-section view of nanomagnetic sticker 100 in accordance with various examples described in the present disclosure. As shown in FIG. 1, nanomagnetic sticker 100 may include base layer 110, adhesive layer 120, and print layer 130. In some examples, base layer 110 may comprise paper. In other examples, base layer 110 may include cardboard, a thin layer of plastic, or any other material suitable to be printed upon with ink.

As shown in FIG. 1, adhesive layer 120 may be located on a first side of base layer 110, for example, the bottom side of base layer 110. Print layer 130 may be located on a second side of base layer 110 opposite from the first side. For example, print layer 130 may be located on the upper side of base layer 110. Print layer 130 may include patterned ink 131. In some examples, the patterned ink 131 may form a bar code. In the same or other examples, the patterned ink 131 may include text or other patterns.

Nanomagnetic sticker 100 may also include a plurality of nanomagnetic particles. For example, nanomagnetic particles may be embedded in adhesive layer 120. The nanomagnetic particles may comprise particles of iron (Fe), nickel (Ni), cobalt (Co), or any other suitable magnetic material. In some examples, the nanomagnetic particles may comprise an alloy or an oxide of a magnetic element, such as iron (Fe), nickel (Ni), or cobalt (Co), among others. The nanomagnetic particles may be, for example, particles with a diameter of 10 nm or less. The small size of the nanomagnetic particles may allow the nanomagnetic particles to be embedded within the adhesive material of adhesive layer 120.

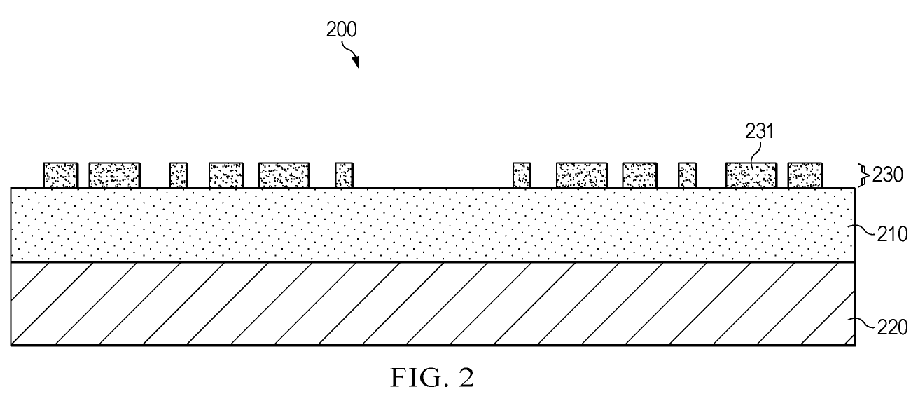

FIG. 2 illustrates a side cross-section view of nanomagnetic sticker 200 in accordance with various examples described in the present disclosure. As shown in FIG. 2, nanomagnetic sticker 200 may include base layer 210, adhesive layer 220, and print layer 230. In some examples, base layer 210 may comprise paper. In other examples, base layer 210 may include cardboard, a thin layer of plastic, or any other material suitable to be printed upon with ink.

As shown in FIG. 2, adhesive layer 220 may be located on a first side of base layer 210, for example, the bottom side of base layer 210. Print layer 230 may be located on a second side of base layer 210 opposite from the first side. For example, print layer 230 may be located on the upper side of base layer 210. Print layer 230 may include patterned ink 231. In some examples, the patterned ink 231 may form a bar code. In the same or other examples, the patterned ink 231 may include text or other patterns.

Nanomagnetic sticker 200 may also include a plurality of nanomagnetic particles. For example, as shown in FIG. 2, nanomagnetic particles may be embedded in the patterned ink 231 of print layer 230. The nanomagnetic particles may comprise, for example, particles of iron (Fe), nickel (Ni), cobalt (Co), or any other suitable magnetic material. In some examples, the nanomagnetic particles may comprise an alloy or an oxide of a magnetic material, such as iron (Fe), nickel (Ni), or cobalt (Co), among others. The nanomagnetic particles may be, for example, particles with a diameter of 10 nm or less. The small size of the nanomagnetic particles may allow the nanomagnetic particles to be embedded within the patterned ink 231 of print layer 230, which may form a barcode for example.

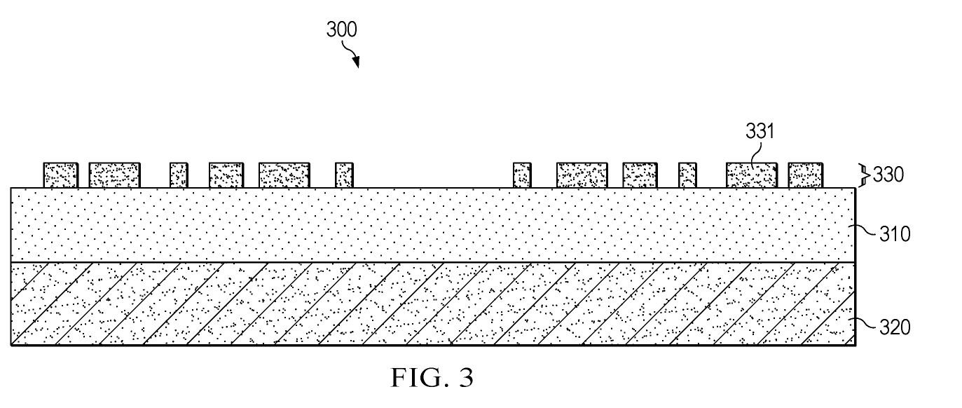

FIG. 3 illustrates a side cross-section view of nanomagnetic sticker 300 in accordance with various examples described in the present disclosure. As shown in FIG. 3, nanomagnetic sticker 300 may include base layer 310, adhesive layer 320, and print layer 330. In some examples, base layer 310 may comprise paper. In other examples, base layer 310 may include cardboard, a thin layer of plastic, or any other material suitable to be printed upon with ink.

As shown in FIG. 3, adhesive layer 320 may be located on a first side of base layer 310, for example, the bottom side of base layer 310. Print layer 330 may be located on a second side of base layer 310 opposite from the first side. For example, print layer 330 may be located on the upper side of base layer 310. Print layer 330 may include patterned ink 331. In some examples, the patterned ink 331 may form a bar code. In the same or other examples, the patterned ink 331 may include text or other patterns.

Nanomagnetic sticker 300 may also include a plurality of nanomagnetic particles. For example, as shown in FIG. 3, nanomagnetic particles may be embedded in adhesive layer 320 as well as in the patterned ink 331 of print layer 330. The nanomagnetic particles may comprise, for example, particles of iron (Fe), nickel (Ni), cobalt (Co), or any other suitable magnetic material. In some examples, the nanomagnetic particles may comprise an alloy or an oxide of a magnetic element, such as iron (Fe), nickel (Ni), or cobalt (Co), among others. The nanomagnetic particles may be, for example, particles with a diameter of 10 nm or less. The small size of the nanomagnetic particles may allow the nanomagnetic particles to be embedded within the adhesive layer 320 as well as within the patterned ink 331 of print layer 330, which may form a barcode for example.

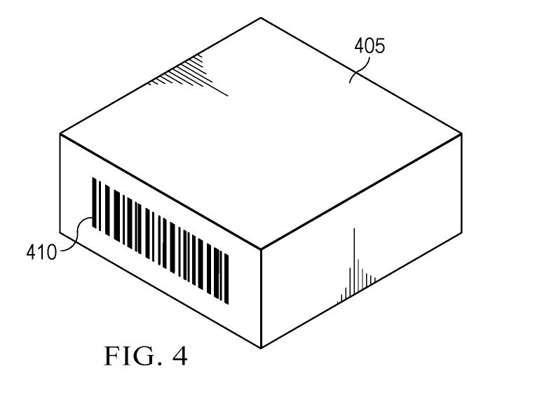

FIG. 4 illustrates a perspective view of retail product 405 with a nanomagnetic barcode 410 in accordance with various examples described in the present disclosure. As shown in FIG. 4, nanomagnetic barcode 410 may be printed directly on a surface of retail product 405. In some examples, nanomagnetic barcode 410 may be printed on the packaging for retail product 405. In other examples, nanomagnetic barcode 410 may be printed directly on retail product 405 itself.

Nanomagnetic barcode 410 may be printed with an ink that may have a plurality of nanomagnetic particles embedded therein. For example, nanomagnetic barcode 410 may include a plurality of nanomagnetic particles embedded in patterned ink forming a barcode. The nanomagnetic particles may comprise, for example, particles of iron (Fe), nickel (Ni), cobalt (Co), or any other suitable magnetic material. In some examples, the nanomagnetic particles may comprise an alloy or an oxide of a magnetic element, such as iron (Fe), nickel (Ni), or cobalt (Co), among others. The nanomagnetic particles may be, for example, particles with a diameter of 10 nm or less.

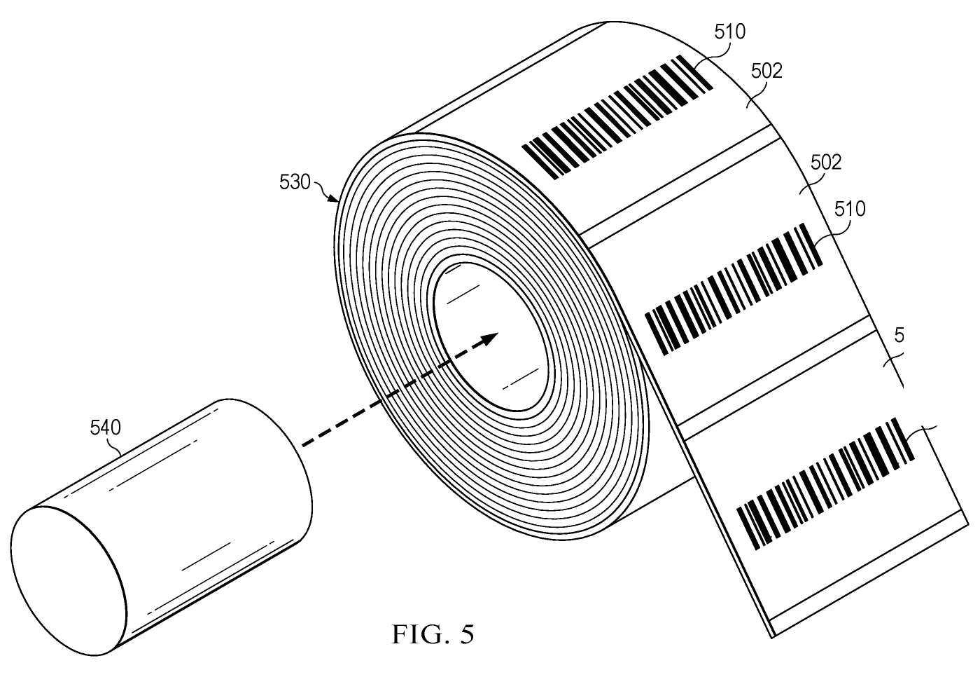

FIG. 5 illustrates a perspective view of a roll 530 of nanomagnetic stickers 502 in accordance with various examples in the present disclosure. The nanomagnetic stickers 502 included in roll 530 may represent an example of any of nanomagnetic sticker 100 (FIG. 1), nanomagnetic sticker 200 (FIG. 2), or nanomagnetic sticker 300 (FIG. 3) described above. Thus, as described above with reference to FIGS. 1, 2, and 3, each of the nanomagnetic stickers 502 may include a base layer, an adhesive layer located on a first side of the base layer, and print layer located on the second side of the base layer and including patterned ink 510. As shown in FIG. 5, the patterned ink 510 of each nanomagnetic sticker 502 may form a barcode. Further, similar to the examples described above with reference to FIGS. 1, 2, and 3, each instance of nanomagnetic sticker 502 may include a plurality of nanomagnetic particles embedded in the adhesive layer, embedded in the patterned ink 510, or embedded in both the adhesive layer and the patterned ink 510. The nanomagnetic particles may comprise, for example, particles of iron (Fe), nickel (Ni), cobalt (Co), or any other suitable magnetic material. In some examples, the nanomagnetic particles may comprise an alloy or an oxide of a magnetic element, such as iron (Fe), nickel (Ni), or cobalt (Co), among others. The nanomagnetic particles may have a diameter of 10 nm or less to facilitate embedding the particles in at least one of the adhesive layer and the patterned ink 510.

As shown in FIG. 5, the roll 530 of nanomagnetic stickers 502 may be disposed around magnetic core 540. Magnetic core 540 may be formed with a strong permanent magnet material. For example, magnetic core 540 may be formed with neodymium-iron-boron (NdFeB) or any other suitable material having a high energy density and strong magnetic properties. Magnetic core 540 may thus be configured to magnetize the plurality of nanomagnetic particles included in each of the nanomagnetic stickers 502 included within roll 530. For example, during or after the manufacture of roll 530, magnetic core 540 may be inserted into a cylindrical space at the center of roll 530. Roll 530 may thus include magnetic core 540 during the time at which roll 530 is stored and shipped to a warehouse or to a retail site, where the nanomagnetic stickers 502 may be applied to consumer products. The storage and transit time may take, for example, one week to one-hundred weeks. During this storage and transit time, magnetic core 540 may magnetize each of the nanomagnetic stickers 502, and particularly the nanomagnetic particles embedded in each of the nanomagnetic stickers 502 included in roll 530. After receiving roll 530 or after dispensing each of the nanomagnetic stickers 502 included within roll 530, magnetic core 540 may be returned to the manufacturer. The manufacturer may then reuse magnetic core 540 within a new instance of roll 530. Such return and reuse of magnetic core 540 may thus spread the cost of magnetic core 540 over many instances of roll 530 and the nanomagnetic stickers 502 included therein. Such return and reuse of magnetic core 540 may therefore facilitate the cost-efficient use of otherwise expensive materials, such as NdFeB, to provide a strong magnetization of the nanomagnetic stickers 502.

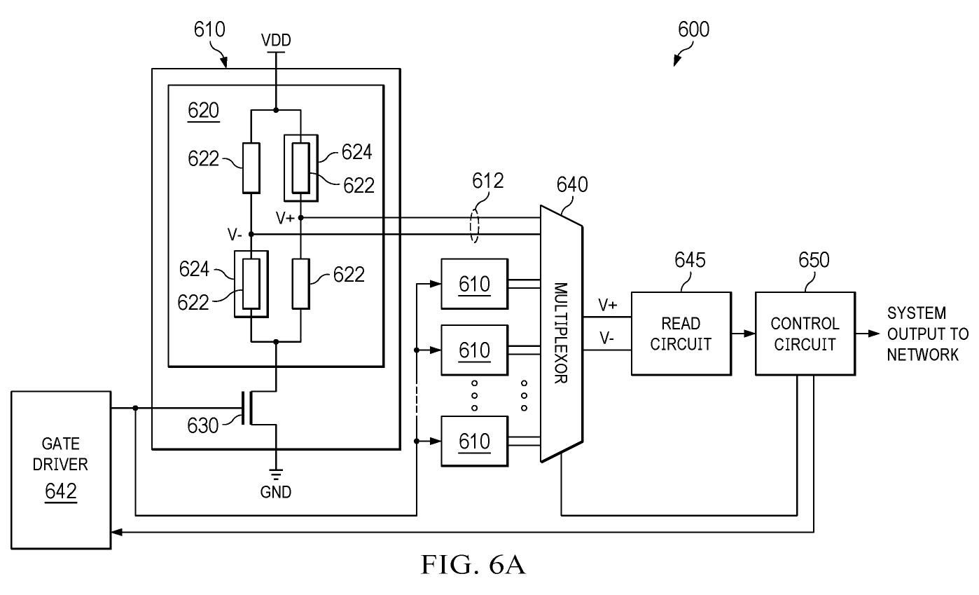

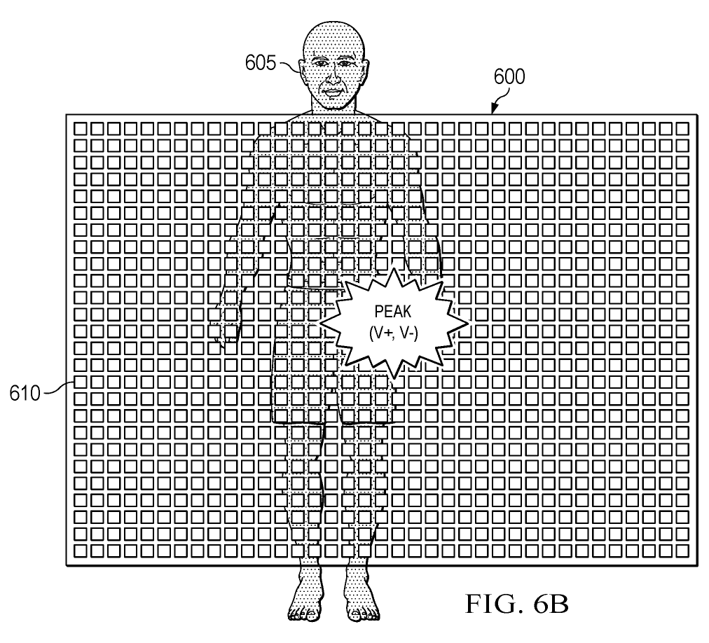

When in use, the magnetized (and not yet demagnetized) nanomagnetic stickers 502 may be detected by magnetic detection systems, such as magnetic detection system 600, described below with reference to FIGS. 6A, 6B, and 7. The attempted theft of a retail product with a nanomagnetic sticker or nanomagnetic barcode applied thereto may thus be detected by a magnetic detection system. Upon legitimate purchase of a retail product with a nanomagnetic sticker or nanomagnetic barcode applied thereto, the retail store may demagnetize the nanomagnetic sticker or nanomagnetic barcode. Thus, the legitimately purchased item will not trip the magnetic detection system.

FIG. 6A illustrates a schematic diagram of magnetic detection system 600 in accordance with various examples described in the present disclosure. Magnetic detection system 600 may be implemented in any suitable fashion according to the operation described in the present disclosure. In some examples, magnetic detection system 600 may include a plurality of sensor cells 610, multiplexor 640, gate driver 642, read circuit 645, and control circuit 650. For simplicity, the internal circuitry of the plurality of sensor cells 610 is shown for a single instance of sensor cell 610. Each instance of sensor cell 610 may have the same internal circuitry as shown in the illustrative example in FIG. 6A.

Sensor cells 610 may be implemented in any suitable fashion according to the operation described in the present disclosure. In some examples, each sensor cell 610 may include a tunnel magnetoresistance (TMR) sensor 620 and a thin-film transistor 630 coupled to enable the TMR sensor 620. As shown in FIG. 6A, TMR sensor 620 may include two branches, each branch including two magnetic-tunnel junctions 622 coupled in series to each other. For example, each of the two branches may include two magnetic-tunnel junctions 622 coupled in series with each other between a power supply line VDD and thin-film transistor 630, which may in turn be coupled to ground GND. The electrical resistance of the magnetic-tunnel junctions 622 may vary based on the presence of a magnetic material (such as the magnetized nanomagnetic particles embedded in any of nanomagnetic stickers 100, 200, 300, and 502). Further, as shown in FIG. 6, opposingly positioned instances of magnetic-tunnel junction 622 in the first branch and the second branch may be magnetically shielded by instances of shield 624. For example, in a first branch, the upper instance of magnetic-tunnel junction 622 coupled to VDD may be magnetically shielded by a first instance of shield 624. Further, in a second branch, the lower instance of magnetic-tunnel junction 622 coupled to thin-film transistor 630 may be magnetically shielded by a second instance of shield 624. Thus, in the presence of a magnetic material, the varying resistances of the unshielded instances of magnetic-tunnel junction 622 may vary the voltage potential at an intermediate node of the first branch (indicated by V+) in an opposite direction as the voltage potential at an intermediate node of the second branch (indicated by V-). Thus, when enabled by thin-film transistor 630, TMR sensor 620 may provide a differential sense signal 612 indicating the presence of a magnetized nanomagnetic sticker or nanomagnetic barcode. In some examples, the strength of the detected magnetic field may indicate how close the magnetized nanomagnetic sticker or nanomagnetic barcode is to the TMR sensor 620 within sensor cell 610. Thus, as a magnetized nanomagnetic sticker or nanomagnetic barcode gets closer to the TMR sensor 620 within sensor cell 610, the differential sense signal 612 indicating the differential between V+ and V- may increase. Likewise, as a magnetized nanomagnetic sticker or nanomagnetic barcode gets further away from the TMR sensor 620 within sensor cell 610, the differential sense signal 612 indicating the differential between V+ and V- may decrease.

Control circuit 650 may be implemented in any suitable fashion according to the operation described in the present disclosure. Control circuit 650 may be configured to periodically scan each of the plurality of sensor cells 610. In some examples, control circuit 650 may synchronously control gate driver 642 and multiplexor 640. For example, gate driver 642 may drive the gate of a thin-film transistor 630 of a selected instance of sensor cell 610 to enable that instance of sensor cell 610. When gate driver 642 enables the selected instance of sensor cell 610, multiplexor 640 may select and pass the differential sense signal 612 from that selected instance of sensor cell 610 to read circuit 645. Read circuit 645 may detect the voltage differential (the voltage difference between V+ and V-) of the differential sense signal 612 for the selected sensor cell 610, and provide a read out to control circuit 650 for the selected sensor cell 610. Each of the plurality of sensor cells 610 may be selected and enabled, for example one at a time, in a repeating and periodic manner.

As described in further detail below with reference to FIG. 6B, the plurality of sensor cells 610 may be arranged in a two-dimensional array. Control circuit 650 may thus be configured to detect the presence and location of a nanomagnetic sticker based on a plurality of sense signals from the plurality of sensor cells 610 disposed in the two-dimensional array. Although sensor cell 610 is described above as including a TMR sensor 620 and a thin-film transistor 630, each sensor cell 610 may include any suitable magnetic sensor. For example, in some examples, the plurality of sensor cells may be implemented with a plurality of hall-effect sensors or a plurality of graphene-hall effect sensors arranged in a two-dimensional array.

FIG. 6B illustrates magnetic detection system 600 in accordance with various examples described in the present disclosure. As shown in FIG. 6B, the plurality of sensor cells 610 may be arranged in a two-dimensional array forming a panel. The panel may be configured with any suitable number of sensor cells 610. For example, the panel may be configured with one thousand, ten thousand, one-hundred thousand, one million, ten million, or more sensor cells 610 arranged in a two-dimensional array. Further the panel may be configured with any suitable height and width. In some examples, the panel may be 24 inches tall by 48 inches long for example. In other examples, the panel may be configured at a height and length to detect the presence of a magnetized (and not yet demagnetized) nanomagnetic sticker or nanomagnetic barcode affixed to a product being carried by a person 605 walking past the panel.

When a consumer purchases a retail product with a nanomagnetic sticker or nanomagnetic barcode applied thereto, the retail store may demagnetize the nanomagnetic sticker or barcode. Otherwise, if a person leaves the retail store without paying for a product, the nanomagnetic sticker or barcode may remain in a magnetized state. When the person 605 subsequently walks past the panel, magnetic detection system 600 may detect the presence and location of the stolen retail product with a magnetized nanomagnetic sticker or magnetized nanomagnetic barcode. For example, presence of a nanomagnetic sticker at a given location relative to the panel may cause a gradient in the strength of the magnetic field detected by the plurality of different sensor cells 610 disposed at varied distances from the corresponding location on the panel. The detected gradient (a change in the detected magnetic field over a change in distance) may thus provide information regarding the presence of a magnetized nanomagnetic sticker or magnetized nanomagnetic barcode and also the precise location of the nanomagnetic sticker or nanomagnetic barcode relative to the two-dimensional array of sensor cells 610 within the panel.

As described above, the plurality of sensor cells 610 may be periodically scanned. Control circuit 650 may thus collect the data from each of the sensor cells 610 to create an image of magnetic fields corresponding to the area of the panel. Control circuit 650 (FIG. 6A) may periodically scan each sensor cell 610 multiple times per second (for example, ten, twenty, one-hundred, one-hundred and twenty, two-hundred, two-hundred and forty, or more times per second). In some examples, the magnetic field image provided by the plurality of sensor cells 610 may be updated at a rate faster than a human would walk or run past magnetic detection system 600. Accordingly, control circuit 650 may track the location and movement of a magnetized (and not yet demagnetized) nanomagnetic sticker or nanomagnetic barcode over time. For example, control circuit may track the location and movement of an abnormal moving magnetic field created by the magnetized (and not yet demagnetized) nanomagnetic sticker or nanomagnetic barcode over time. To the extent that the size and number of pixels in magnetic detection system 600 may be limited by the speed of sensor cells 610, read circuit 645, or control circuit 650, a panel may be formed with multiple instances of magnetic detection system 600 operating in parallel to each other to form a large panel or plurality of panels suitable to the application.

In some examples, magnetic detection system 600 may be located either at an exit of a retail store or in a communal area of a retail shopping center, such as an indoor mall or an outdoor market. When placed in a communal area of a retail shopping center, magnetic detection system 600 may provide theft detection for many retail stores utilizing the nanomagnetic stickers or nanomagnetic barcodes. Such communal use of magnetic detection system 600 may spread the cost of the magnetic detection system 600 across numerous participating retail stores, thus providing cost-efficient theft detection for numerous retailers who may individually bear the cost of the nanomagnetic stickers but share the cost of the magnetic detection system 600. In some examples, the shared cost of the magnetic detection system 600 may be paid, for example, through subscription payments or as part of the rent paid by individual retail stores to the management company of the retail shopping center.

In some applications, magnetic detection system 600 may be coupled to a larger security network. For example, the location information from magnetic detection system 600 may be synchronized with security camera video of the same area. By synchronizing magnetic detection system 600 to security camera video, the security network may help security personnel identify individuals with stolen retail products that tripped magnetic detection system 600.

FIG. 7 illustrates security system 700 in accordance with various examples described in the present disclosure. Security system 700 may be implemented in any suitable fashion according to the operation described in the present disclosure. Security system 700 may include multiple instances of magnetic detection system 600, including for example magnetic detection systems 600a and 600b. Magnetic detection systems 600a and 600b may be placed in an alternating fashion with television monitors 710a and 710b. In the event that magnetic detection system 600a or 600b detects the presence of a magnetized (and not yet demagnetized) nanomagnetic sticker or nanomagnetic barcode as person 605 walks past, security system 700 may output on television monitors 710a or 710b a video and audio warning or command to person 605 to return the detected items. If the detected stolen merchandise was not in fact stolen, person 605 may return to the retail store or other location within the retail shopping center to have the nanomagnetic sticker or nanomagnetic barcode demagnetized so as not to trip magnetic detection systems 600a or 600b.

In some examples, security system 700 may invoke other security measures to stop the theft of a detected stolen merchandise. For example, in response to detected theft, security system 700 may invoke a human or humanoid policeman or security personnel to instruct the person 605 to stop and return the stolen items. As another example, in response to detected theft, security system 700 may invoke a Wi-Fi message or other wireless message to the cell phone of person 605. Such a wireless message may indicate to person 605 which part of the body of person 605 has the abnormal magnetic field (such as left front pocket, right ankle, or other). Such a message to person 605 may also instruct person 605 to return to the retail store to either return any stolen items or to check if a nanomagnetic sticker or nanomagnetic barcode applied to a purchased product was not properly demagnetized after a legitimate purchase of the detected retail product.

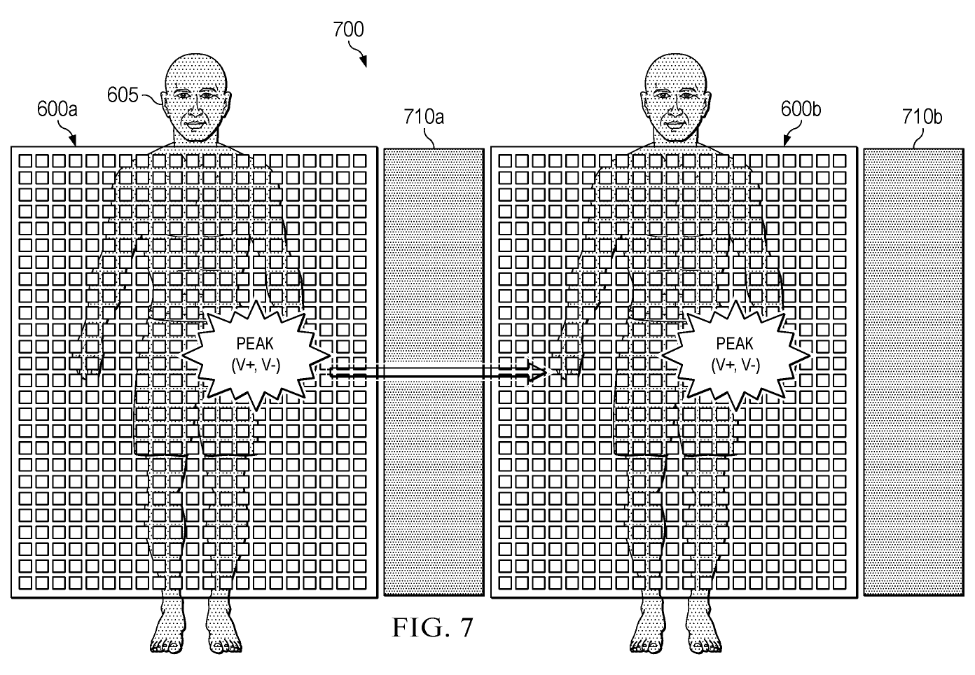

FIG. 8 illustrates a flow chart of an example method 800 for fabricating a nanomagnetic sticker in accordance with various examples in the present disclosure. According to one example, method 800 may begin at block 802. Teachings of the present disclosure may be implemented in a variety of configurations of nanomagnetic sticker 100, nanomagnetic sticker 200, nanomagnetic sticker 300, and roll 530 of nanomagnetic stickers 502. As such, the initialization point for method 800 and the order of 802-808 comprising method 800 may depend on the implementation chosen.

At block 802, method 800 may include forming a sticker having a base layer and an adhesive layer located on a first side of the adhesive layer. At block 804, method 800 may include forming a print layer on a second side of the base layer including patterned ink. At block 806, method 800 may include embedding a plurality of nanomagnetic particles in at least one of the patterned ink and the adhesive layer. In some examples, the plurality of nanomagnetic particles are embedded in the adhesive layer. In further examples, the plurality of nanomagnetic particles are embedded in the patterned ink. In yet further examples, the plurality of nanomagnetic particles are embedded in both the adhesive layer and the patterned ink. At block 808, method 800 may include magnetizing the plurality of nanomagnetic particles. In some examples, magnetizing the plurality of nanomagnetic particles includes placing the sticker in a roll around a magnetic core. In the same or different examples, the magnetic core comprises neodymium-iron-boron (NdFeB).

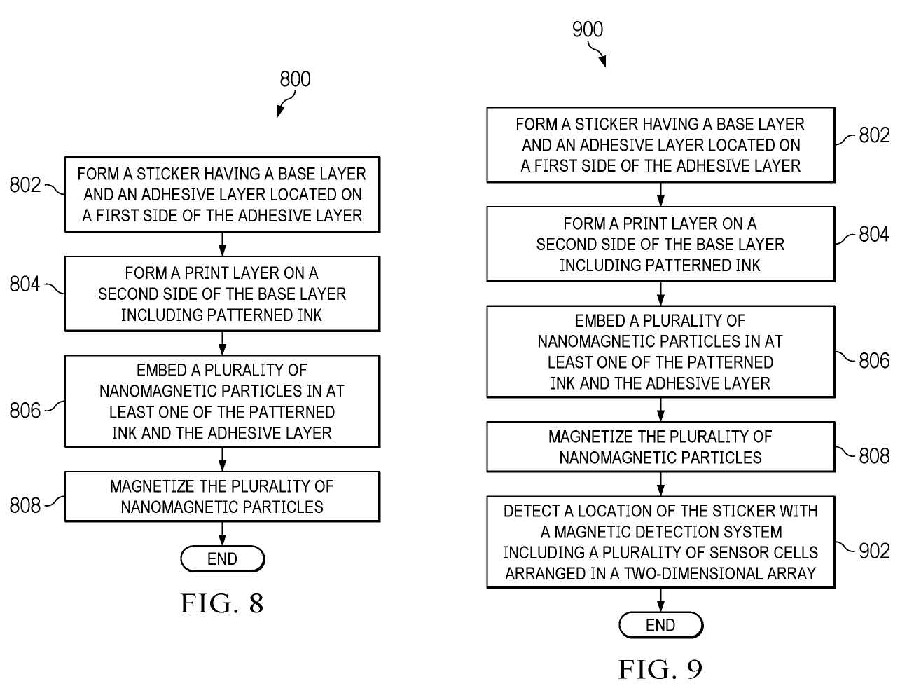

Although FIG. 8 discloses a particular number of operations related to method 800, method 800 may be executed with greater or fewer operations than those depicted in FIG. 8. For example, after block 808, method 800 may continue with additional operations illustrated in FIG. 9. In addition, although FIG. 8 discloses a certain order of operations to be taken with respect to method 800, the operations comprising method 800 may be completed in any suitable order. For example, the nanomagnetic particles may be embedded in the ink (block 806) that will be used to form the patterned ink prior to the formation of the print layer on the second side of the base layer (block 804). As another example, the nanomagnetic particles may be embedded in an adhesive material (block 806) that will be used to form the adhesive layer prior to the formation of the sticker having a base layer and an adhesive layer (block 802).

FIG. 9 illustrates a flow chart of an example method 900 for detecting a nanomagnetic sticker in accordance with various examples in the present disclosure. According to one example, method 900 may begin at block 902. In some examples, method 900 may begin with blocks 802-808 (FIG. 8) and then proceed to block 902. At block 902, method 900 may include detecting a location of the sticker with a magnetic detection system including a plurality of sensor cells arranged in a two-dimensional array.

Although FIG. 9 discloses a particular number of operations related to method 900, method 900 may be executed with greater or fewer operations than those depicted in FIG. 9. In addition, although FIG. 9 discloses a certain order of operations to be taken with respect to method 900, the operations comprising method 900 may be completed in any suitable order.

Although examples have been described above, other variations and examples may be made from this disclosure without departing from the spirit and scope of these disclosed examples.

1. A nanomagnetic sticker comprising:
a base layer;
an adhesive layer located on a first side of the base layer;
a print layer located on a second side of the base layer, the print layer comprising patterned ink; and
a plurality of nanomagnetic particles embedded in at least one of the adhesive layer and the patterned ink.

2. The nanomagnetic sticker of claim 1, wherein the plurality of nanomagnetic particles are embedded in the adhesive layer.

3. The nanomagnetic sticker of claim 1, wherein the plurality of nanomagnetic particles are embedded in the patterned ink.

4. The nanomagnetic sticker of claim 1, wherein the plurality of nanomagnetic particles are embedded in the adhesive layer and in the patterned ink.

5. The nanomagnetic sticker of claim 1, wherein the patterned ink forms a bar code.

6. The nanomagnetic sticker of claim 1, wherein the base layer comprises paper.

7. The nanomagnetic sticker of claim 1, wherein the base layer comprises plastic.

8. The nanomagnetic sticker of claim 1, wherein the nanomagnetic sticker is wrapped in a roll disposed around a magnetic core.

9. The nanomagnetic sticker of claim 8, where the magnetic core comprises neodymium-iron-boron (NdFeB).

10. A magnetic detection system, comprising:
a plurality of sensor cells arranged in a two-dimensional array, wherein each of the plurality of sensor cells includes:
a tunnel magnetoresistance (TMR) sensor; and
a transistor coupled to enable the TMR sensor; and
a control circuit configured to periodically scan each of the plurality of sensor cells.

11. The magnetic detection system of claim 10, wherein the control circuit is configured to detect a location of a nanomagnetic sticker or a nanomagnetic barcode based on a plurality of sense signals from the plurality of sensor cells located across the two-dimensional array.

12. The magnetic detection system of claim 11, wherein the nanomagnetic barcode includes a plurality of nanomagnetic particles embedded in patterned ink forming a barcode.

13. The magnetic detection system of claim 11, wherein the nanomagnetic sticker comprises:
a base layer;
an adhesive layer located on a first side of the base layer;
a print layer located on a second side of the base layer, the print layer comprising patterned ink; and
a plurality of nanomagnetic particles embedded in at least one of the adhesive layer and the patterned ink.

14. The magnetic detection system of claim 10, wherein the transistor is a thin-film transistor.

15. A method comprising:
forming a sticker having a base layer and an adhesive layer located on a first side of the base layer;
forming a print layer on a second side of the base layer including patterned ink;
embedding a plurality of nanomagnetic particles in at least one of the patterned ink and the adhesive layer; and
magnetizing the plurality of nanomagnetic particles.

16. The method of claim 15, further comprising detecting a location of the sticker with a magnetic detection system including a plurality of sensor cells arranged in a two-dimensional array.

17. The method of claim 15, wherein magnetizing the plurality of nanomagnetic particles includes placing the sticker in a roll around a magnetic core.

18. The method of claim 17, wherein the magnetic core comprises neodymium-iron-boron (NdFeB).

19. The method of claim 15, wherein the plurality of nanomagnetic particles are embedded in the adhesive layer.

20. The method of claim 15, wherein the plurality of nanomagnetic particles are embedded in the patterned ink.
